(19) United States
(12) Patent Application Publication
(10) Pub. No.: US 2007/0258199 A1
(43) Pub. Date: Nov. 8, 2007

(54) PLASMA DISPLAY PANEL DEVICE

(75) Inventor: Kwang-Jin JEONG, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung SDI Co., Ltd., Suwon-si (KR)

(21) Appl. No.: 11/735,017

(22) Filed: Apr. 13, 2007

(30) Foreign Application Priority Data
May 2, 2006 (KR) 2006-39555

(51) Int. Cl. G06F 1/16; H05K 7/20; H01J 61/52

(52) U.S. Cl. 361/681; 313/46; 361/690

(57) ABSTRACT

A plasma display panel device including a panel to display an image, a chassis base coupled to a rear surface of the panel, a thin metal plate interposed between the panel and the chassis base, a plurality of driving boards applying an electrical signal to discharge electrodes patterned within the panel, and a case to house the panel, the chassis base, the thin metal plate, and the driving boards. The chassis base is in the shape of a frame, so that the manufacturing costs of the chassis base are drastically reduced.

### CROSS-REFERENCE TO RELATED APPLICATIONS

This application claims the benefit of Korean Application No. 2006-39555, filed May 2, 2006, in the Korean Intellectual Property Office, the disclosure of which is incorporated herein by reference.

### BACKGROUND OF THE INVENTION

1. Field of the Invention

Aspects of the present invention relate to a plasma display panel device, and more particularly, to a plasma display panel device having a chassis base that is structurally improved.

2. Description of the Related Art

Typically, plasma display panel (PDP) devices are flat panel display devices that display desired numbers, characters, and graphics, by applying a discharge voltage to a discharge gas within a panel. The panels include a plurality of electrodes arranged to generate ultraviolet (UV) rays, and excite a phosphor material with the UV rays.

Referring to FIG. 1, a conventional plasma display panel device 100 includes: a panel 110; a flat chassis base 120 installed on the rear side of the panel 110; driving boards 130 mounted on the rear side of the chassis base 120; a filter 140 installed in front of, and separated from, the panel 110; and a case 150 to house the panel 110, the chassis base 120, the driving board 130, and the filter 140.

The conventional plasma display panel device 100, having the above-described structure, can be manufactured by assembling: the panel 110; coupling the chassis base 120 to the rear side of the panel 110; installing the driving boards 130 on the rear side of the chassis base 120; installing the filter 140 in front of, and separated from the panel 110; and disposing the panel 110, the chassis base 120, the driving boards 130, and the filter 140 in the case 150.

Recently, however, flat panel liquid crystal display (LCD) devices have been manufactured to be 40 or more inches, and are competing with PDP devices. Also, improvements in the mass production of the LCD devices have caused a rapid drop in the prices of the devices.

Accordingly, various solutions for reducing the manufacturing costs of PDP devices have been proposed. Some proposed solutions include, changing the shape of the chassis base to be coupled with a panel, or reducing the number of driving boards by using an improved a driving method for applying a voltage to the discharge electrodes.

A chassis base has a heat discharging function, and an electrical function. The heat discharging function includes discharging heat from the panel, the driving boards, etc., and the electrical function includes electrically grounding the driving boards, and shielding the electromagnetic wave generated by the panel.

Recent developments of PDP devices have been made, for drastically reducing the amount of heat emitted by a panel, and other components, and for reducing the number of driving boards. Hence, the structure of a chassis base, to be coupled with the panel and the driving boards, needs to be changed, so that the chassis base has both a good heat discharging capability, and a good electrical functionality.

### SUMMARY OF THE INVENTION

Aspects of the present invention provide a plasma display device having a good heat discharging capability, and an good electrical functionality, These aspects are realized by changing the structure of a part, on which a chassis base coupled to a panel, is installed.

According to an aspect of the present invention, there is provided a plasma display panel device including a panel displaying an image, a chassis base coupled to a rear surface of the panel, a thin metal plate interposed between the panel and the chassis base, a plurality of driving boards to apply an electrical signal to discharge electrodes patterned within the panel, and a case to house the panel, the chassis base, the thin metal plate, and the driving boards.

The chassis base can be a frame formed by arranging a plurality strips. The frame is formed by vertically and horizontally connecting the plurality of strips to one another. Bosses grounded to the thin metal film, protrude from the frame, and grounding boards are installed on the bosses. A heat conduction sheet is interposed between the panel and the thin metal plate. Some of the driving boards can be installed within the case.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic view illustrating a structure of a related art plasma display panel (PDP) device;

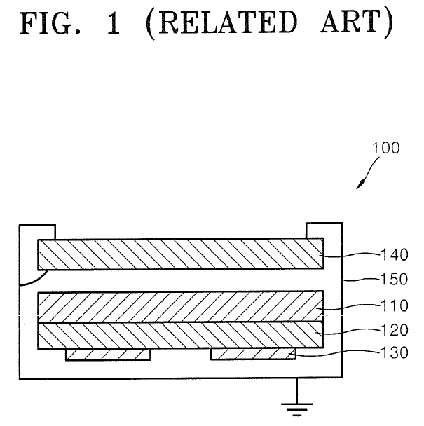

FIG. 2 is an exploded perspective view of a PDP device, according to an embodiment of the present invention;

FIG. 3 is a cross-sectional view of the PDP device illustrated in FIG. 2, when assembled; and

FIG. 4 is an exploded perspective view of a PDP device, in an assembled state, according to another embodiment of the present invention.

### DETAILED DESCRIPTION OF THE EMBODIMENTS

Reference will now be made in detail to the various embodiments of the present invention, examples of which are illustrated in the accompanying drawings, wherein like reference numerals refer to the like elements throughout. The embodiments are described below in order to explain the present invention, by referring to the figures

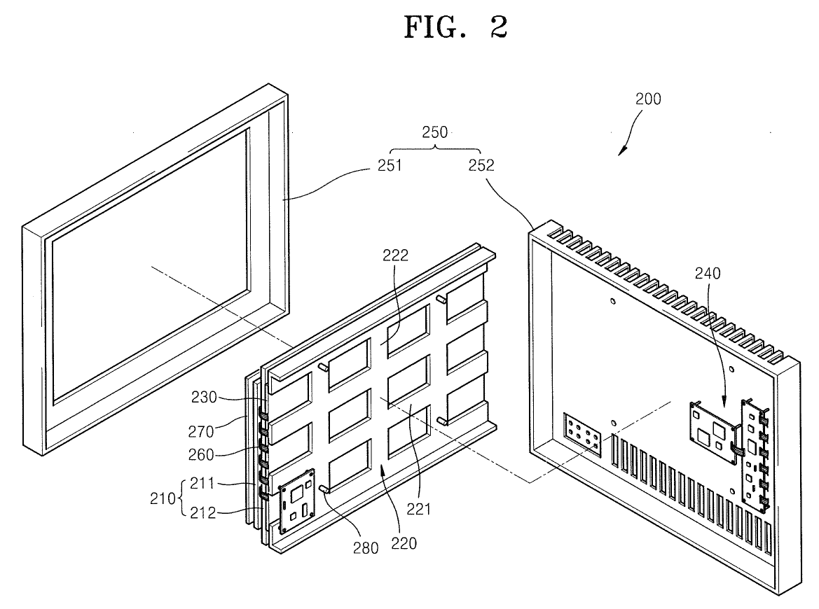

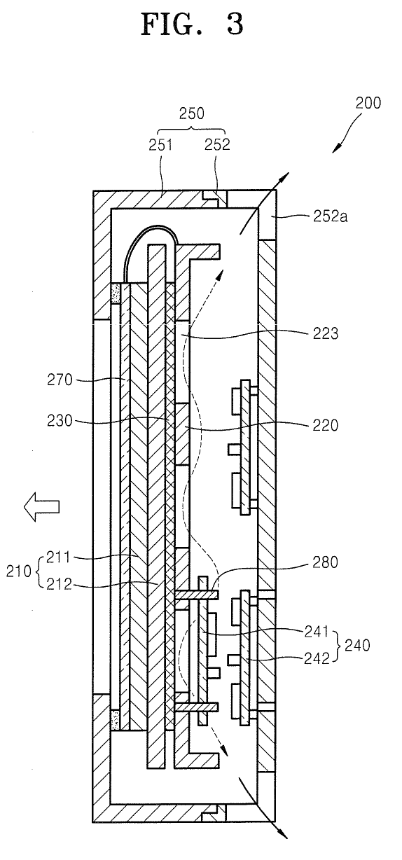

FIG. 2 is an exploded perspective view of a PDP device 200, according to an embodiment of the present invention. FIG. 3 is a cross-sectional view of the PDP device 200 when assembled.

Referring to FIGS. 2 and 3, the PDP device 200 includes: a panel 210; a chassis base 220 coupled to the rear surface of the panel 210; a thin metal plate 230 interposed between the panel 210 and the chassis base 220; a plurality of driving boards 240 to apply an electrical signal to discharge electrodes arranged within the panel 210; and a case 250 to house the panel 210, the chassis base 220, the thin metal plate 230, and the driving boards 240.

The panel 210 includes a first substrate 211, and a second substrate 212, that face each other, and are spaced apart. A sealant (not shown) is coated on the edges of the opposing surfaces of the first and second substrates 211 and 212, so that an enclosed discharge space is formed therebetween.

To reduce the number of driving boards 240, the locations of discharge electrodes, patterned within the panel 210, are concentrated on one side of each of the first and second substrates 211 and 212. The terminals of the discharge electrodes are electrically connected to a terminal of a signal transmission unit 260 with, for example, flexible printed cables.

The chassis base 220 is coupled to the rear surface of the panel 210. The chassis base 220 is not a flat metal plate, having a size corresponding to that of the panel 210 as in the conventional art, but is a frame formed by connecting a plurality of strips to one another.

In the present embodiment, the chassis base 220 includes a plurality of horizontal strips 221 and a plurality of vertical strips 222, which are connected to one another, to be formed into one body. Hence, spaces 223, defined by the horizontal and vertical strips 221, 222, are formed. Alternatively, the horizontal strips 221 and the vertical strips 222 may be separated from each other.

The chassis base 220 may be formed of a highly thermal-conductive material, such as, aluminum, in order to rapidly discharge the heat generated by the panel 210. The chassis base 220 may comprise of a non-metal, such as, a complex material or a composite material, in order to reinforce the strength of the chassis base 220.

The chassis base 220 should be structurally robust, should supplement the electrical grounding of the driving boards 240, and should be shielded from the electromagnetic waves generated by the panel 210.

To achieve this, the thin metal plate 230 is disposed between the chassis base 220 and the second substrate 212. The thin metal plate 230 is formed of a highly thermal-conductive metal, such as, aluminum, and is directly attached to the rear surface of the second substrate 212. The thin metal plate 230 can be a metal film, foil, or layer.

The chassis base 220 is shown directly attached to the thin metal plate 230. Alternatively, the chassis base 220 may be separated from the second substrate 212 by an adhesive member, such as, a double-stick tape attached on both ends of the chassis base 220.

A plurality of bosses 280 are installed on the chassis base 220. The bosses 280 may be used to fix grounding boards 241, on which grounding patterns are formed, in order to shield the electromagnetic waves generated by the panel 210. The bosses 280 may be used to hang the panel 210 on an external fixed body or mounting.

To fix the grounding boards 241, the bosses 280 pass through the chassis base 220, and are fixed to the thin metal plate 230. The bosses 280 protrude from the rear of the panel 210, such that the grounding boards 241 can be installed at the bosses 280.

Driving boards 242, for applying an electrical signal to discharge electrodes patterned within the panel 210, can be installed in and/or on the case 250. The case 250 includes a front case 251 installed in front of the panel 210, and a back cover 252 installed at the rear of the chassis base 220. The driving boards 242 are fixed onto the back cover 252.

A filter 270 is directly attached to the front of the plasma display panel 211. The filter 270 is formed of a plurality of films. The filter 270 includes an anti-reflection (AR) film that prevents a drop in visible recognition due to the reflection of the external light, an electromagnetic shielding filter that effectively shields electromagnetic waves generated when the plasma display panel 200 is driven, and a selective wavelength absorption film that shields neon luminescence in a 590 nanometer area and unnecessary luminescence of near infrared rays caused by plasma of inactive gas used to emit light from a screen. The filter 270 may include additional films having various additional functions. However, it is understood that the filter 270 need not be used or can be otherwise disposed in other aspects of the invention.

To achieve these functions, the filter 270 includes: a reflection-preventing film to prevent visual degradation due to the reflection of external light; an electromagnetic wave shielding layer to shield the electromagnetic waves generated during the driving of the panel 210; and a selective wavelength absorbing film to shield unnecessary emission of near infrared light, due to an inert gas, namely, plasma, used during light emissions from a screen, and neon emissions. The filter 270 may further include a stack of the other various films.

When the PDP device 200 receives an external voltage, the panel 210 is driven to display an image. When the panel 210 is driven, heat is generated from the panel 210, and the heat passes through the thin metal plate 230, attached to the second substrate 212, and is discharged through the chassis base 220. In the chassis base 220, the spaces 223 are defined by the integrated horizontal strips 221 and the vertical strips 222.

Accordingly, the heat generated from the panel 210 is convected to ambient air, entering through bent holes 252a formed in the back cover 252, and flowing within the spaces 223. This convection accelerates the discharge of heat from the PDP device 200.

The electromagnetic waves, generated from the panel 210, are grounded and/or absorbed by the filter 270, attached to the front surface of the first substrate 211. Also, the electromagnetic waves, generated from the panel 210, are conducted through the thin metal plate 230, and are absorbed by the grounding boards 241, in a circuit-like manner. In this way, the electromagnetic waves, generated from the panel 210, are shielded.

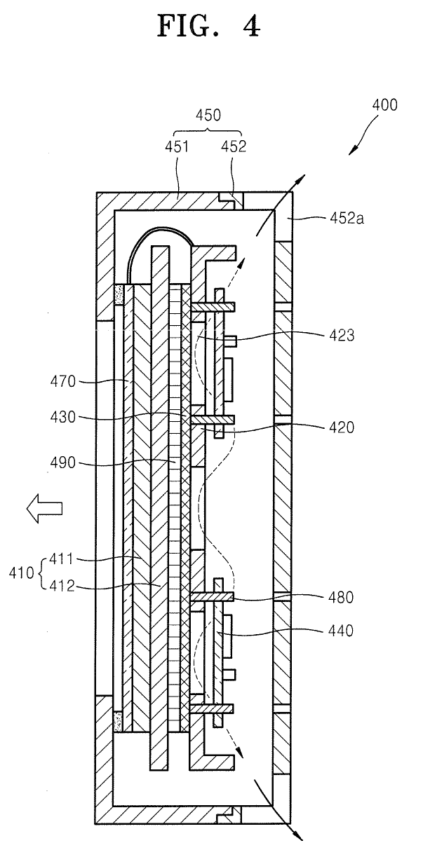

FIG. 4 is an exploded perspective view of a PDP device 400, in an assembled state, according to another embodiment of the present invention.

Referring to FIG. 4, the PDP device 400 includes: a panel 410; a chassis base 420 coupled to the rear surface of the panel 410; a thin metal plate 430 interposed between the panel 410 and the chassis base 420; a heat conduction sheet 490 interposed between the panel 410 and the thin metal plate 430; a plurality of driving boards 440 to apply electrical signals to discharge electrodes patterned within the panel 410; and a case 450 to house the panel 410, the chassis base 420, the thin metal plate 430, the heat conduction sheet 490, and the driving boards 440.

The panel 410 includes a first substrate 411, and a second substrate 412 spaced apart from, and attached to, the first substrate 411. The first substrate 411 and the second substrate 412 are space apart to form an area to display an image.

The chassis base 420 is installed on the rear surface of the second substrate 412. The chassis base 420 is not a flat metal plate corresponding to the panel 410, but rather is a frame formed by connecting a plurality of strips to one another. The strips can have a vertical or horizontal orientation. The chassis base can be formed as a grid or an array. The vertically orientated strips can be disposed orthogonally to the horizontally oriented strips.

To have a robust structure, the chassis base 420 is formed by connecting a plurality of structures having H-shaped or I-shaped, cross sections. A plurality of spaces 423 defined in the chassis base 420, are disposed on the rear surface of the panel 410. The chassis base 420 is formed of a metal, such as aluminum, or a non-metal, such as a complex or composite material, or a combination thereof.

The thin metal plate 430 is disposed in front of the chassis base 420, and faces the panel 410. The thin metal plate 430 is formed of a highly thermal-conductive metal, such as, aluminum, and is directly attached to the front surface of the chassis base 420, or is separated a predetermined distance from the second substrate 412, by an adhesive member, such as, a double-stick tape attached on both ends of the chassis base 420. The thin metal plate 430 can be a metal film, foil, or layer.

The heat conduction sheet 490 is interposed between the second substrate 412 and the thin metal plate 430. One surface of the heat conduction sheet 490 is directly attached to the rear surface of the second substrate 412, and the other surface thereof contacts the thin metal plate 430.

The heat conduction sheet 490 has a size corresponding to the size of the panel 410, and is preferably formed of a highly thermal-conductive material, such as, graphite or silicon. The heat conduction sheet 490 transmits the heat generated by the panel 410, during the operation of the PDP device 400, to the chassis base 420, via the thin metal plate 430.

A plurality of bosses 480 are installed on the chassis base 420. The driving boards 440, including grounding boards for shielding an electromagnetic waves generated by the panel 410, are fixed to the bosses 480. The bosses 480 may be used to hang the panel 410 on an external fixed body, or mounting. The bosses 480 can be used to secure the panel 410 to the back cover 452 of the case 450

One end of each of the bosses 480 passes through the chassis base 420, to form a ground to the thin metal plate 430, and the other ends thereof protrude from the rear surface of the chassis base 420. The driving boards 440, such as, grounding boards on which grounding patterns are formed, or boards electrically connected to the discharge electrodes of the panel 410, are installed oh the bosses 480.

A filter 470 is directly attached to the front surface of the first substrate 411. The filter 470 is formed of a plurality of films. The filter 470 includes an anti-reflection (AR) film that prevents a drop in visible recognition due to the reflection of the external light, an electromagnetic shielding filter that effectively shields electromagnetic waves generated when the plasma display panel 400 is driven, and a selective wavelength absorption film that shields neon luminescence in a 590 nanometer area and unnecessary luminescence of near infrared rays caused by plasma of inactive gas used to emit light from a screen. The filter 470 may include additional films having various additional functions. However, it is understood that the filter 470 need not be used or can be otherwise disposed in other aspects of the invention.

The case 450 includes a front case 451 installed in front of the panel 410, and a back cover 452 installed at the rear of the chassis base 420. In contrast with the embodiment of FIG. 3, no driving boards are installed on the back cover 452.

In the PDP device 400, the heat generated from the panel 410, during the operation of the panel 410, is conducted through the heat conduction sheet 490, attached to the rear surface of the second substrate 412, and the thin metal plate 430, attached to the rear surface of the heat conduction sheet 490, and is then discharged through the chassis base 420.

Due to frame structure of the chassis base 420, ambient air enters through bent holes 452a formed in the back cover 452, and the heat is exchanged with the ambient air, within the spaces 423. This convection contributes to cooling the panel 410.

The electromagnetic waves generated by the panel 410, are grounded and/or absorbed by the filter 470 attached to the front surface of the first substrate 411. Also, the electromagnetic waves generated by the panel 410 are conducted through the thin metal plate 430, attached to the rear surface of the second substrate 412, and are conducted through the grounding boards, included in the driving boards 440, in a circuit-like manner. In this way, the electromagnetic waves generated from the panel 410 are shielded.

A PDP device, according to aspects of the present invention as described above, has the following attributes. First, since a chassis base is in the shape of a frame, the manufacturing costs of the chassis base are drastically reduced. In addition, since a thin metal plate is installed between a panel and the chassis base, the grounding characteristics are improved. Furthermore, since a heat conduction sheet is installed between the panel and the chassis base, the heat generated from the panel is effectively discharged.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A plasma display panel device, comprising:
a panel to display an image;
a chassis base coupled to a rear surface of the panel;
a metal plate interposed between the panel and the chassis base;
a plurality of driving boards to apply electrical signals to discharge electrodes patterned within the panel; and
a case to house the panel, the chassis base, the metal plate, and the driving boards.

2. The plasma display panel device of claim 1, wherein the chassis base is a frame comprising a plurality of strips disposed upon one another.

3. The plasma display panel device of claim 2, wherein the plurality of strips are disposed orthogonally to one another.

4. The plasma display panel device of claim 2, wherein the chassis base comprises metal.

5. The plasma display panel device of claim 2, wherein the chassis base comprises a non-metal material.

6. The plasma display panel device of claim 2, further comprising bosses disposed on the frame to hang the panel on an external fixed body.

7. The plasma display panel device of claim 2, wherein the driving boards are disposed upon on the frame.

8. The plasma display panel device of claim 2, further comprising bosses attached to the metal plate protrude on the frame, and grounding boards are installed on the bosses.

9. The plasma display panel device of claim 1, wherein the metal plate comprises aluminum.

10. The plasma display panel device of claim 1, wherein a heat conduction sheet is interposed between the panel and the metal plate.

11. The plasma display panel device of claim 10, wherein the heat conduction sheet comprises one of graphite and silicon.

12. The plasma display panel device of claim 1, wherein some of the driving boards are disposed upon the case.

13. The plasma display panel device of claim 1, wherein an electromagnetic wave shielding filter is directly attached to a front surface of the panel.

14. The plasma display panel device of claim 2, wherein the plurality of strips have one of an H-shaped cross section and an L-shaped cross section.

15. The plasma display panel device of claim 1, wherein the chassis base is a metal frame having an array of holes defined therein.

16. The plasma display panel device of claim 1, wherein the chassis base comprises one of a highly heat-conductive metal, a composite material or a combination thereof.

17. The plasma display panel device of claim 1, further comprising bosses to connect the panel, the chassis base, and the thin metal plate to the case.

18. The plasma display panel device of claim 17, wherein the bosses protrude a back surface of the cover, and are to secure the chassis base to an external mount.

19. The plasma display panel device of claim 13, wherein the case comprises holes to allow ambient air into the case.
